(19) United States
(12) Patent Application Publication
(10) Pub. No.: US 2022/0088740 A1
(43) Pub. Date: Mar. 24, 2022

(54) SEMICONDUCTOR WAFER PHOTOELECTROCHEMICAL MECHANICAL POLISHING PROCESSING DEVICE AND PROCESSING METHOD

(71) Applicant: DALIAN UNIVERSITY OF TECHNOLOGY, Dalian, Liaoning (CN)

(72) Inventors: Zhigang DONG, Dalian, Liaoning (CN); Kang SHI, Dalian, Liaoning (CN); Renke KANG, Dailan, Liaoning (CN); Liwei OU, Dalian, Liaoning (CN); Xianglong ZHU, Dalian, Liaoning (CN); Shang GAO, Dalian, Liaoning (CN)

(21) Appl. No.: 17/413,939

(22) PCT Filed: Dec. 13, 2019
(86) PCT No.: PCT/CN2019/125072

§ 371 Date: Jun. 14, 2021

(30) Foreign Application Priority Data
Dec. 14, 2018 (CN) 201811537195.8
Dec. 14, 2018 (CN) 201811537196.2

(51) Int. Cl. B24B 7/22; B24B 37/04; B24B 37/10; H01L 21/306; C09G 1/02; C09K 3/14

(52) U.S. Cl. CPC B24B 7/228; B24B 37/042; B24B 37/10; H01L 29/2003; C09G 1/02; C09K 3/1409; H01L 21/30625

(57) ABSTRACT

A semiconductor wafer is adhered and fixed to a polishing head by means of a conductive adhesive, and the wafer is connected to a positive electrode of an external power supply through wires of the inner and outer rings of a conductive slip ring below the wafer. A polishing pad is adhered to the bottom of a counter electrode disc, the counter electrode disc is fixed at the bottom of a polishing disc and is processed with through holes at the position corresponding to the polishing disc, and the counter electrode disc is connected to a negative electrode of the external power supply through the wires of inner and outer rings of a conductive slip ring above the counter electrode disc. Ultraviolet light emitted by an ultraviolet light source can reach the surface of the wafer through the through holes, and a polishing solution can be sprayed through the through holes into a contact area between the wafer and the polishing pad.

### TECHNICAL FIELD

The present disclosure relates to the technical field of polishing processing, and more particularly, to a semiconductor wafer photoelectrochemical mechanical polishing processing device and processing method.

### BACKGROUND

The third generation semiconductor materials represented by gallium nitride (GaN), silicon carbide (SiC) and diamond, because of their high thermal conductivity, high breakdown electric field, high electron saturation rate and high radiation resistance performance, are more suitable than the previous generation semiconductor materials for producing devices with high temperature, high frequency, high power and radiation resistant.

When GaN and SiC crystal materials are used as devices, higher surface quality and no surface/subsurface damage such as scratch, microcrack, low dislocation and residual stress are required. However, GaN and SiC crystal materials have large bond energy, strong chemical inertness and almost no chemical reaction with any acid-base reagents at room temperature, which is categorized as the typical hard, brittle, and difficult-to-process material. In the processing of the two kinds of materials, diamond abrasive particles are usually used for grinding and lapping in order to achieve better surface quality and higher flatness. However, due to the high hardness of diamond abrasive particles, it will inevitably cause surface/subsurface damage to the wafer. Hideo Aida et al. (Applied Surface Science 292 (2014) 531-536) constantly reduced the damage depth of the GaN wafer by reducing the diamond particle size in the GaN grinding process. When the particle size of the diamond abrasive particle was reduced to 500 nm and 50 nm, the subsurface damage depth of the GaN wafer also reached 1.6 μm and 0.26 μm. In order to completely remove the subsurface damage of the 500 nm and 50 nm diamond after grinding processing, the subsequent chemical mechanical polishing (CMP) with SiO₂ abrasive particles took 150 hours and 35 hours respectively.

It can be seen that in the processing of traditional CMP to remove the subsurface damage, the very high chemical inertness of the material makes the removal rate of the polishing process very low, which leads to a series of problems such as long processing time and high cost.

### SUMMARY OF THE INVENTION

According to the technical problems mentioned in the above background, the present disclosure studies and designs a semiconductor wafer photoelectrochemical mechanical polishing processing method and designs a set of processing device for the method. The photoelectrochemical mechanical polishing method in the present disclosure refers to a processing method in which ultraviolet light is introduced to directly irradiate the semiconductor workpiece on the basis of the existing chemical mechanical polishing, and the photoelectrochemical oxidation is produced under the action of an external electric field and ultraviolet light, and then the oxide modified layer of the semiconductor wafer is removed by mechanical polishing.

On the one hand, the present disclosure provides a semiconductor photoelectrochemical mechanical polishing processing method: a semiconductor wafer photoelectrochemical mechanical polishing processing method, mechanically polishing a wafer; mechanically polishing a polishing piece having through holes; during polishing, ultraviolet light irradiating the wafer through the through holes; during polishing, the polishing solution dripping on the surface of the wafer through the through holes, and the polishing solution including abrasive particles; and during polishing, the wafer being used as an anode and being modified by photoelectrochemical oxidation under an external electric field.

As a preferred technical solution, the polishing piece includes polishing disc and polishing pad, and the layout of the through holes of the polishing disc is constant with that of the polishing pad; and the polishing disc is used as the cathode in the method.

As a preferred technical solution, the method includes the following steps:

S1. fixing the wafer to a polishing head by means of conductive adhesive, after driving, the wafer rotating axially with the polishing head, wherein the polishing head is an electric conductor; adhering the polishing pad to the polishing disc, after driving, the polishing pad contacting the wafer surface and producing a relative motion;

S2. applying a positive potential to the wafer and a negative potential to the polishing disc; and

S3. during polishing, ultraviolet light irradiating the wafer by successively passing through the through holes of the polishing disc and the polishing pad; and the polishing solution impregnating a contact area between the wafer and the polishing pad by the through holes of the polishing disc and the polishing pad.

As a preferred technical solution, the polishing piece includes the polishing disc and the polishing pad, the counter electrode disc having through holes is arranged between the polishing disc and the polishing pad as a cathode; and the layouts of the through holes of the polishing disc, the counter electrode disc and the polishing pad are consistent.

As a preferred technical solution, the method includes the following steps:

S1. fixing the wafer to the polishing head by means of conductive adhesive, after driving, the wafer rotating axially with the polishing head, wherein the polishing head is an electric conductor; adhering the polishing pad to the counter electrode disc (the counter electrode disc of the present disclosure refers to the disc-shaped counter electrode material), and fixing the counter electrode disc to the polishing disc, after driving, the polishing pad contacting the wafer surface and producing a relative motion, wherein the counter electrode disc has through holes;

S2. applying a positive potential to the wafer and a negative potential to the counter electrode disc; and

S3. during polishing, ultraviolet light irradiating the wafer by successively passing through the through holes of the polishing disc, the counter electrode disc and the polishing pad; and the polishing solution impregnating a contact area between the wafer and the polishing pad by the through holes of the polishing disc, the counter electrode disc and the polishing pad.

As a preferred technical solution, the wafer is connected to the positive electrode of the external power supply and the cathode to the negative electrode of the external power supply; and the external power supply, the wafer and the cathode form a closed circuit.

As a preferred technical solution, the area ratio of photoelectrochemical action and mechanical action of the device is 1:12 to1:1.

As a preferred technical solution, the polishing disc and the polishing pad are located above the semiconductor wafer, and the ultraviolet light source is located above the polishing disc.

As a preferred technical solution, the abrasive particle is cerium oxide or silicon oxide; a preferred particle size of the abrasive particle is 6 nm to 100 nm; a preferred concentration of the abrasive particle is 0.05-10 wt. %; a supply flow of the polishing solution is 50 mL/min to 100 mL/min; and a rotational speed of the wafer is 100 rpm to 250 rpm, a rotational speed of the polishing disc is 60 to 150 rpm, a polishing pressure is 4 to 6.5 psi, and an intensity of ultraviolet light is 50 to 175 mW·cm⁻².

As a preferred technical solution, the semiconductor wafer is a gallium nitride wafer.

As a preferred technical solution, the ultraviolet light source is at least one of low-pressure mercury lamp, high-pressure mercury lamp, LED mercury lamp, deuterium lamp and xenon lamp, and the wavelength is less than 400 nm.

The area ratio of photoelectrochemical action to mechanical action in the present disclosure refers to: according to the diameters and quantities of the through holes of the polishing pad and the polishing disc, the area of the through holes in contact with the wafer is calculated, that is the ratio of the area exposed by the through holes on the wafer surface (photoelectrochemical oxidation action occurs on the wafer surface of the portion irradiated by ultraviolet light) to the remaining area covered by the polishing pad on the wafer surface (this portion is mechanically polished by the polishing pad) is recorded as the area ratio of photoelectrochemical action to mechanical action.

In order to achieve the above photoelectrochemical mechanical polishing processing method, on the other hand, the present disclosure studies and designs a photoelectrochemical mechanical polishing processing device. The method combined with the processing device can obtain a processing effect of faster removal rate.

The technical solution of a semiconductor wafer photoelectrochemical mechanical polishing device of the present disclosure is:

A semiconductor wafer photoelectrochemical mechanical polishing processing device, including: a polishing pad having through holes; a polishing disc having through holes, which is used to drive the polishing pad to mechanically polish a surface of a wafer; a polishing solution source, which is used to supply the polishing solution, and the polishing solution dripping on the wafer surface through the through holes of the polishing disc and the polishing pad; an ultraviolet light source, which is used to supply ultraviolet light, and the ultraviolet light irradiating on the wafer through the through holes of the polishing disc and the polishing pad; and an external power supply. The wafer is connected to the positive electrode of the external power supply, and the polishing disc is connected to the negative electrode of the external power supply. The external power supply, the wafer and the polishing disc form a closed circuit.

Another photoelectrochemical mechanical polishing processing device, including: a polishing pad having through holes; a polishing disc having through holes, which is used to drive the polishing pad to mechanically polish a surface of a wafer; a counter electrode disc having through holes, which is arranged between the polishing disc and the polishing pad; a polishing solution source, which is used to supply the polishing solution, the polishing solution dripping on the wafer surface through the through holes of the polishing disc and the polishing pad; an ultraviolet light source, which is used to supply ultraviolet light, the ultraviolet light irradiating the wafer through the through holes of the polishing disc and the polishing pad; and an external power supply. The wafer is connected to the positive electrode of the external power supply, and the counter electrode disc is connected to the negative electrode of the external power supply. The external power supply, the wafer and the counter electrode disc form a closed circuit.

As a preferred technical solution, the polishing solution is a chemical polishing solution which includes abrasive particles.

As a preferred technical solution, the polishing disc and the polishing pad are located above the wafer, and the ultraviolet light source is located above the polishing disc and the polishing pad.

As a preferred technical solution, the polishing solution source is a polishing solution spray head which is located above the polishing disc.

As a preferred technical solution, the through holes of the polishing disc are arranged radially from the center of the polishing disc to the periphery; preferably, the through holes are arranged periodically along the radial direction of the polishing disc; preferably, a center part of the polishing disc is not provided with through hole, and only a position where the peripheral part of the polishing disc contacts with the wafer is provided with the through holes.

As a preferred technical solution, the layouts of the through holes of the polishing disc, the counter electrode disc and the polishing pad are consistent.

As a preferred technical solution, the external power supply provides at least one of a direct-current power supply, a potentiostat, an electrochemical workstation and a dry battery.

As a preferred technical solution, an area of the polishing pad is greater than that of the wafer; a preferred radius of the polishing pad is greater than the diameter of the wafer; a preferred radius of the polishing disc is greater than the diameter of the wafer; and preferrably, the through holes of the polishing pad are arranged a the part in contact with the wafer.

As a preferred technical solution, an area ratio of photoelectrochemical action and mechanical action of the device is 1:12 to1:1.

Preferably, through holes are only processed at the circular ring of the contact area between the polishing pad and the wafer, and a preferred width of the ring is the wafer diameter.

Preferably, the distribution of the through holes on the polishing pad can be radially distributed at the circumference with different diameters from the center of the polishing pad, or can be uniformly distributed in a certain number on at the circumference with different diameters instead of radially.

As a preferred technical solution, the device also includes a polishing solution collecting tank in which the polishing head and the polishing disc are arranged.

As a preferred technical solution, the polishing pad is one of polyurethane polishing pad, nonwoven polishing pad and velvet cloth polishing pad.

Compared with the prior art, the photoelectrochemical mechanical polishing method and the polishing device thereof involved in the present disclosure have the following advantages:

(1) High Polishing Removal Efficiency

The present disclosure adopts the method of irradiating the wafer surface with ultraviolet light through the through holes and applying electric potential to the wafer and the counter electrode disc respectively (the wafer as the anode and the counter electrode disc as the cathode) to combine the photoelectrochemical action, thus the wafer can be modified by oxidation efficiently, and then the oxide modified layer can be mechanically removed by the polishing pad and the abrasive particles. During processing, the wafer and the polishing disc respectively rotate to produce a relative motion. At the same time, the ultraviolet radiation, the potential difference between the wafer and the counter electrode, and the feeding of the polishing solution make the photoelectrochemical modification action and mechanical polishing action alternate to carry out photoelectrochemical mechanical processing on the wafer. The photoelectrochemical modification action and mechanical polishing action are performed alternately. The method of present disclosure combines the photoelectrochemical modification and mechanical polishing, which can achieve the advantages of fast polishing removal rate and low roughness of the wafer after polishing.

(2) The Ratio of the Photoelectrochemical Modification Action to the Mechanical Polishing Action Can Be Adjusted.

The diameters and the quantities of the through holes on the polishing disc and the polishing pad at the bottom, and the through holes layout on the polishing disc can be artificially optimized, thus the ratio of the photoelectrochemical modification action to the mechanical polishing action of the wafer in the photoelectrochemical mechanical polishing process (i.e., the area ratio of the photoelectrochemical action to the mechanical action) can be adjusted and optimized at will.

(3) No Oxidizer is Required in the Polishing Process.

In the wafer polishing process, the electron hole pairs excited by ultraviolet light can be separated by the potential applied by the external electric field, and no additional oxidizer is required in the polishing solution to capture the photo-generated electrons to promote the separation of electron-hole.

(4) The Processing Device is Simple and the Processing Method is Easy to Realize.

The processing parameters of the processing device such as the polishing pressure, the rotational speed of the wafer, the rotational speed of the polishing pad, the solution type and concentration, the intensity of the ultraviolet light source, the area ratio of photochemical to mechanical action, and the potential difference between the wafer and the counter electrode can be adjusted according to the actual workpiece type to achieve better processing effect.

### DETAILED DESCRIPTION OF DRAWINGS

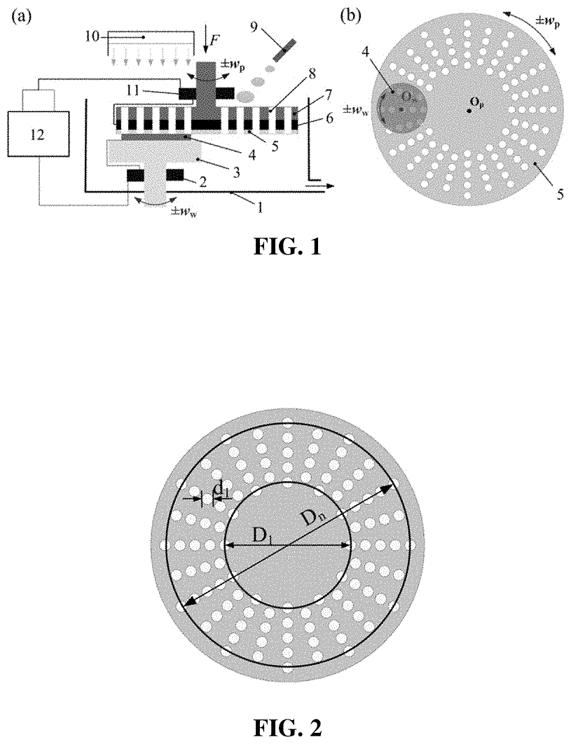

FIG. 1 is a schematic diagram of the semiconductor wafer photoelectrochemical mechanical polishing method in the present disclosure.

FIG. 2 is a schematic diagram of the through holes on the counter electrode disc, the polishing disc and the polishing pad of the semiconductor wafer photoelectrochemical mechanical polishing method in the present disclosure.

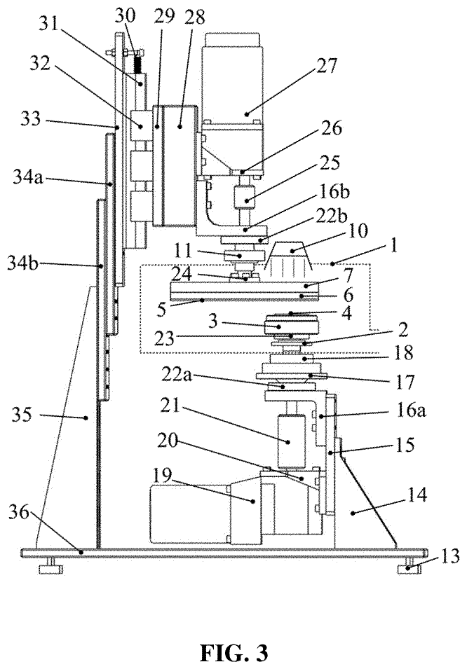

FIG. 3 is a schematic diagram of the semiconductor wafer photoelectrochemical mechanical polishing device in the present disclosure.

The components of each identification in FIG. 3 are:

13. leveling screw, 14. right-angled fixed plate, 15. adapter panel, 16a. L-shaped support plate, 17. flange plate, 18. outer spherical bearing, 2. conductive slip ring, 19. right-angled motor, 20. motor bracket, 21. elastic coupling, 22a. crossed roller bearing, 23. step shaft I, 3. polishing head, 5. polishing pad, 24. step shaft II, 11. conductive slip ring, 4.wafer, 6. counter electrode disc, 7.polishing disc, 1. polishing solution tank, 10. ultraviolet light source, 25. elastic coupling, 26. motor bracket, 27. motor, 28. adapter panel, 29. module panel, 30. spring, 31. guide rail, 32. sliding block; 33. module baseplate, 34a and 34b. vertical support plates, 35. right-angled support plate, 36. baseplate.

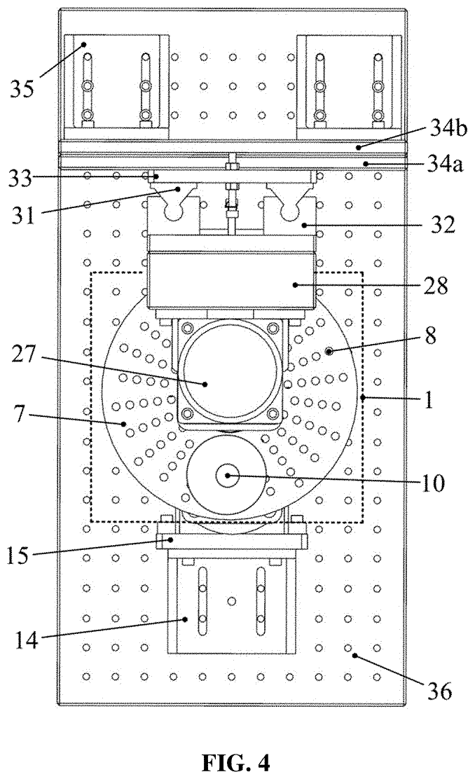

FIG. 4 is a top view of the semiconductor wafer photoelectrochemical mechanical polishing processing device in the present disclosure.

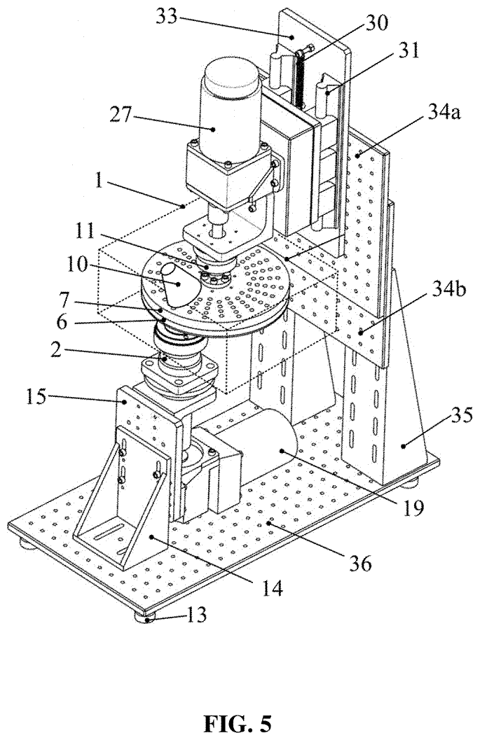

FIG. 5 is an axial view of the semiconductor wafer photoelectrochemical mechanical polishing device in the present disclosure.

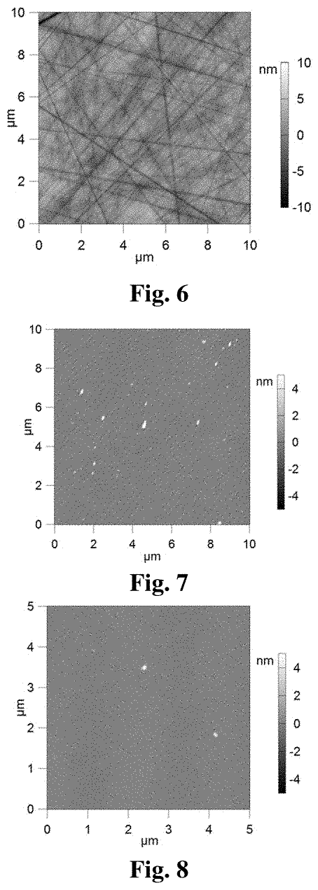

FIG. 6 is the surface original morphology of the GaN wafer, and the surface roughness value of Ra is 1.16 nm.

FIG. 7 is the surface morphology of the GaN wafer after photoelectrochemical mechanical polishing with the processing condition of embodiment 1, and the wafer surface roughness value of Ra is 0.48 nm.

FIG. 8 is the surface morphology of the GaN wafer after photoelectrochemical mechanical polishing under with processing condition of embodiment 2, and the wafer surface roughness value of Ra is 0.1 nm (The field of view of the atomic force microscope is 5×5 μm²).

### DETAILED DESCRIPTION OF PREFERRED EMODIMENTS

The present disclosure is further described hereinafter with reference to the attached drawings.

(1) The wafer is fixed to the polishing head, after driving, the wafer rotates axially with the polishing head. The wafer is conductive through the adhering of the conductive adhesive and the metal part of the polishing head. The polishing head is connected with the inner ring wire of the conductive slip ring, thereby connected with the outer ring of the conductive slip ring to form a path.

(2) The polishing pad is adhered to the counter electrode disc, and the counter electrode is fixed on the polishing disc. After driving, the polishing pad is in contact with the wafer surface and produces a relative motion. The counter electrode disc can be connected with the inner ring wire of the conductive slip ring, thereby connected with the outer ring wire to form a path.

(3) The counter electrode disc and the polishing disc are processed with through holes, and the polishing pad (preferably pasted at the bottom of the counter electrode disc) is also processed with through holes correspondingly. During polishing, ultraviolet light is located above the polishing disc, and ultraviolet light can directly irradiate on the surface of the wafer through the through holes of the polishing disc, the counter electrode disc and the polishing pad. The polishing solution impregnates the wafer surface through the through holes of the polishing disc, the counter electrode disc and the polishing pad.

(4) The external applied negative potential can successively pass through the outer ring lead of the conductive slip ring above the counter electrode disc to the inner ring lead, thereby connected to the counter electrode disc. The external applied positive potential can successively pass through the outer ring lead of the conductive slip ring below the wafer to the inner ring lead, thereby connected to the wafer. The negative and positive potential applied to the counter electrode disc and the wafer respectively can form a potential difference between them in the processing.

A preferred semiconductor wafer is a gallium nitride wafer.

The photoelectrochemical mechanical polishing method in the present disclosure refers to a processing method, which is based on the existing chemical mechanical polishing, ultraviolet light can directly irradiate the polished semiconductor workpiece through the through holes of the polishing disc, and the external applied electric field can be applied to the semiconductor workpiece and the counter electrode disc in the polishing process, the semiconductor workpiece is modified by photoelectrochemical oxidation under ultraviolet irradiation and the action of the external applied electric field, and the modified layer is followed to be mechanically removed by the polishing pad.

The photoelectrochemical mechanical polishing device includes:

a polishing head used to fix the wafer, and the wafer can be connect to the external circuit by the conductive adhesive between the polishing head and the wafer;

a polishing pad adhered to the counter electrode disc by the adhesive layer on the back of itself;

a counter electrode disc fixed to the polishing disc by the screws and processed with the same through holes as the polishing disc;

a polishing disc connected with the counter electrode disc and having through holes, pressurizing the wafer in the polishing process;

a polishing solution spray head located above the polishing disc and used for spraying the polishing solution; and the supplied polishing solution can enter the polishing area through the through holes;

a first driving and transmission part connected with the polishing disc and used to drive the polishing disc to rotate around a fixed axis;

a second driving and transmission part connected with the polishing head and used to drive the polishing head thereby drive the wafer to rotate with a fixed axis; and

a support part used to support and fix the first drive and transmission part, the second drive and transmission part, the polishing head, the polishing disc and the polishing solution spray head.

The external applied negative potential successively passes through the outer ring lead to the inner ring lead of the conductive slip ring above the counter electrode disc, and then is connects to the counter electrode disc. The external applied positive potential can successively pass through the outer ring lead to the inner ring lead of the conductive slip ring below the wafer, and then connect to the wafer.

The polishing pad is arranged on one side of the counter electrode disc in contact with the wafer surface, and the polishing pad is provided with through holes. The preferred polishing pad is pasted on the bottom of the counter electrode disc, and the through holes are processed on the counter electrode disc and the polishing disc correspondingly.

The polishing disc, the counter electrode disc, and the polishing pad pasted at the bottom are processed with through holes. During the processing of the wafer, the ultraviolet light above the polishing pad in the polishing process can reach the wafer surface through the through holes, and perform light spot chemical oxidation on the wafer with the assistance of the external applied electric filed, so as to make the workpiece irradiated by the ultraviolet light to modify.

Preferably, the polishing disc is connected with the driving motor successively through the connecting shaft and the elastic coupling, and the driving motor can drive the polishing shaft to rotate around a fixed shaft.

The device also includes a polishing solution collecting tank in which the polishing head and the polishing disc are arranged.

In the polishing process, the polishing pressure can be loaded by the polishing disc.

When the polishing pad and the wafer rotate respectively, they can produce a relative speed.

The device also includes a linear module, which includes a module panel, a guide rail, a guide rail sliding block and a module baseplate. The guide rail is fixed on the module baseplate, and the sliding block is fixed with the module panel and can slide straight on the guide rail. The dead-weight of the motor, the adapter panel and the linear module can be used as the source of the processing pressure of the photoelectrochemical mechanical polishing.

A spring is arranged between the module panel and the module baseplate. The processing pressure in the polishing process can be adjusted quantitatively by changing the spring with different stiffness coefficient. When the dead-weight of the whole part does not meet the polishing pressure, additional weight can be added to realize the loading of larger polishing pressure.

The position and size of the through holes on the polishing disc, the counter electrode disc and the polishing pad can be optimized. By changing the size and position of the through holes, the time ratio, of the irradiated part by ultraviolet light to the mechanical polishing part, of the wafer during processing can be adjusted. As shown in FIG. 2, the through holes are uniformly distributed at the concentric circles with different diameters of the polishing disc. The concentric circle radius (D₁ or Dₙ), corresponding to the through holes of each circle, can be optimized; the distance between the concentric circles where the through holes of each circle located can be optimized; and the diameter of each through hole (d₁) and the number of the through holes can be optimized.

In the process of photoelectrochemical mechanical polishing, the wafer and the polishing pad are respectively driven by their driving motor and move relative to each other. The dead-weight of the polishing pad and its driving device provide the processing pressure, ultraviolet light can irradiate the wafer surface through the through holes, and the external applied electric potential can be applied to the wafer and the counter electrode respectively. In the photoelectrochemical mechanical polishing processing, the photoelectric chemical oxidation modification and mechanical polishing are continuously and alternately carried out to polish the wafer.

Referring to FIG. 1:

1. polishing solution tank, 2. conductive slip ring, 3. polishing head, 4. wafer, 5. polishing pad, 6. counter electrode disc, 7. polishing disc, 8. through hole, 9. polishing solution spray head, 10. ultraviolet lamp, 11. conductive slip ring, 12. external power supply. The wafer 4 is adhered and fixed on the polishing head 3 through the conductive adhesive, the inner ring wire of the conductive slip ring 2 can be connected with the wafer 4, and connected to the outer ring wire of the conductive slip ring 2, thereby connected to the positive electrode of the external power supply 12. The inner ring of the conductive slip ring 2 is fastened to the shaft of the polishing head and can rotate with it together. The polishing head 3 can be driven by the motor to rotate together with the wafer. The polishing pad 5 is pasted on the bottom of the counter electrode disc 6 through its adhesive layer on the back, and the counter electrode disc 6 is fixed to the polishing disc 7 through the screws. The counter electrode disc 6 is connected with the inner ring wire of the conductive slip ring 11, thereby connected with the outer ring wire of the conductive slip ring 11, and the outer ring wire of the conductive slip ring 11 is connected to the negative electrode of the external power supply 12. The inner ring wire of the conductive slip ring 11 is fastened on the step shaft of the polishing disc and rotates together with it together. The polishing pad 5, the counter electrode disc 6 and the polishing disc 7 are all processed with through holes. Ultraviolet light emitted by the ultraviolet light source 10 can irradiate the surface of the wafer 4 through the through holes 8, and the polishing solution sprayed by the polishing solution spray head 9 also can enter the contact area between the wafer 4 and the polishing pad 5 through the through holes 8. The wafer 4 is connected with the positive electrode of the external power supply 12, and the counter electrode disc 6 is connected with the negative electrode of the external power supply 12. Conductive medium such as sulfuric acid and potassium sulfate, are added in the polishing solution as support electrolytes. The wafer 4 and the counter electrode disc 6 can be conducted by the polishing solution, and the wafer 4 and the counter electrode disc 6 can be supplied with potential difference by the external power supply 12 during the processing.

The process of the photoelectrochemical mechanical polishing processing method is as follows: The wafer 4 is adhered and fixed on the polishing head 8 by the conductive adhesive, and driven by the motor to rotate together with the polishing head 8. The wafer 4 is connected with the positive electrode of the external power supply 12 successively through the conductive adhesive, the polishing head 3, the inner ring wire of the conductive slip ring 2 and the outer ring wire of the conductive slip ring 2. Ultraviolet light emitted by the ultraviolet light source 10 can irradiate the surface of the wafer 4 through the through holes on the polishing pad 5, the counter electrode disc 6 and the polishing disc 7. The counter electrode disc 6 is connected with the negative electrode of the external power supply 12 successively through the inner ring wire of the conductive slip ring 11 and the outer ring wire of the conductive slip ring 11. The polishing solution sprayed by the polishing solution spray head 9 enters the contract area between the wafer 4 and the polishing pad 5. Conductive medium in the polishing solution, such as sulfuric acid and potassium sulfate, can be used as support electrolytes to fill between the wafer 4 and the counter electrode disc 6 to conduct the counter electrode disc 6 and the wafer 4. The potential difference between the wafer 4 and the counter electrode disc 6 is provided by the external power supply 12. Ultraviolet light emitted by the ultraviolet light source 10 irradiates the surface of the wafer 4, and the ultraviolet irradiation combined with the external applied electric field can produce photochemical oxidation modification on the wafer 4. The polishing pad 5 is pasted at the bottom of the counter electrode disc 6, and the counter electrode disc 6 is connected to the bottom of the polishing disc 7 through the screws; the polishing disc is driven by a motor to rotate, so that the rotation of the polishing pad 5 and the rotation of the wafer 4 produce a relative motion. The polishing pressure F can be loaded to the contact area between the wafer 4 and the polishing pad 7 by the polishing disc 7. After loading pressure, the relative motion of the wafer 4 and the polishing pad 5 can perform mechanical polishing on the wafer 4 to remove the oxide modified layer formed by photoelectrochemical action on the wafer 4. After the oxide modified layer is mechanically removed, a new exposed surface is photoelectrochemically modified again, and the cycle is repeated. Alternate operation of the photoelectrochemical action and mechanical polishing action can perform photochemical and mechanical polishing on wafer 4.

The processing device studied and designed to realize the processing method is described in detail with embodiments:

Referring to FIGS. 3 to 5, the baseplate 36 is supported by 4 leveling screws 13, and the right-angled fixed plate 14 is installed on the baseplate 36 through the screws to support the polishing head 3 and its driving and transmission part. The adapter plate 15 is fixed to the right-angled fixed plate 14 through the screws. The right-angled motor 19 is installed on the motor bracket 20 which is installed on the adapter plate 15 by the screws. The wafer 4 is adhered to the polishing head 3 through the conductive adhesive, and the polishing head 3 is installed on the step shaft 23 through the screws. The portion of the polishing head 3 contacted the conductive adhesive is the metal that can conduct electricity, the metal portion of the polishing head 3 is connected to the inner ring wire of the conductive slip ring 2 which is fastened on the step shaft 23 through the screws, and the inner ring wire can rotate synchronously with the step shaft 23. The outer ring wire of the conductive slip ring 2 is conducted to the inner ring wire, and then the wafer 4 is conducted. A shaft shoulder of the step shaft 23 is mounted on the inner ring of the outer spherical bearing 18. The outer spherical bearing 18 can bear a certain amount of axial load and has a certain self-aligning effect, so that when the wafer 4 and the polishing pad 3 are in contact, due to the small installation error or the surface error between the wafer 4 and the polishing head 3, the wafer 4 and the polishing pad 3 can be in good parallel contact through the appropriate self-aligning effect of the outer spherical bearing 18. The outer spherical bearing 18 is fixed on the flange plate 17 through screws; the flange plate 17 is installed on the inner ring of the crossed roller bearing 22a by screws; the outer ring of the crossed roller bearing 22a is fixed on the L-shaped support plate 16a by screws; and the L-shaped support plate 16a is fixed on the adapter panel 15 by screws. The shaft shoulder of the step shaft 23 is mounted on the inner ring of the outer spherical bearing 18, and successively passes through the flange plate 17 (the shaft diameter is less than the flange aperture), the crossed roller bearing 22a (the shaft diameter is less than the aperture of the bearing inner ring) and the L-shaped support plate 16a (the shaft diameter is less than the aperture of the L-shaped support plate), and is connected with the motor shaft of the right-angled motor 19 through the elastic coupling. The step shaft 23 is used to transfer the driving torque and support the polishing head 3. The polishing pad 5 is adhered to the counter electrode disc 6 by the adhesive layer on the back of itself; the counter electrode disc 6 is installed on the polishing disc 7 by screws. The counter electrode disc 6 and the polishing disc 7 are processed with through holes at the same positions, so that ultraviolet light emitted by the ultraviolet light source 10 and the polishing solution can enter the contact area between the wafer 4 and the polishing pad (which can be seen from the top view of FIG. 4). The polishing solution tank 1 collects and intensively discharges the polishing solution waste liquor. The inner ring of the conductive slip ring 11 is fastened on the step shaft II 24, and the conductive slip ring 11 rotates with the inner ring synchronously. The inner ring wire of the conductive slip ring 11 is connected with the counter electrode disc 6, the potential of the counter electrode disc 6 is connected with the negative electrode of the external power supply successively through the inner ring wire of the conductive slip ring 11 and the outer ring wire. The polishing disc is fixed on the step shaft II 24, and the shaft shoulder of the step shaft II 24 is mounted on the inner ring of the crossed roller bearing 22b. The step shaft II 24 passes through the L-shaped support plate 16b and is connected with the elastic coupling 25, and the other end of the elastic coupling 25 is connected with the motor shaft of the motor 27. The motor 27 is installed on the motor bracket 26 which is fixed on the adapter panel 28 by screws, the adapter panel 28 is installed on the module panel 29 by screws, the module panel 29 is connected with a plurality of sliders 32 which can move in a straight line on the guide rail 31, and the guide rail 31 is installed on the module baseplate 33. The spring 30 is connected in series between the module panel 29 and the module baseplate 33. The polishing pad 5, the counter electrode disc 6, the polishing disc 7, the step shaft II 24, the conductive slip ring 11, the crossed roller bearing 22b, the elastic coupling 25, the motor bracket 26, the motor 27, the adapter panel 28, the module panel 29, the spring 30, the slider 32, the dead-weights of these parts can be used as the source of the polishing pressure during photoelectrochemical mechanical polishing. The polishing pressure can be changed by changing the stiffness coefficient of the spring 30. The module baseplate 33 is fixed on the vertical support plate 34a which is fixed on the vertical support plate 34b. The vertical support plate 34b is fixed on the right-angled support plate 35 by screws, and the right-angled support plate 35 is installed and fixed on the baseplate 36.

The technical effect of the present disclosure is illustrated below by an embodiment realizing the processing method by using a processing device of the present disclosure.

The GaN wafer used in this embodiment is a GaN self-supporting wafer grown by means of HVPE method, having a diameter of 1 inch (25.4 mm) and a wafer thickness of approximately 350 μm. After diamond grinding, the surface morphology of the initial wafer is measured by atomic force microscope, and the initial morphology of the wafer is shown in FIG. 6. In FIG. 6, after grinding with diamond superhard abrasive particles, the surface roughness value of Ra of the initial wafer is 1.16 nm, and a large number of scratches caused by diamond grinding can be seen on the surface.

The wafer removal rate is converted by means of weighing the quality before and after processing by the precision balance and calculating the quality difference before and after processing. Before weighing, acetone, alcohol, hydrofluoric acid and deionized water are successively used to clean the GaN wafer to remove the error of the wafer mass weighing caused by the dust and other adhesive materials attached on the wafer surface.

(1) The GaN wafer is adhered to the wafer fixture by the conductive adhesive, and is conducted with the fixture by the inner ring wire of the conductive slip ring. The wafer fixture is installed on the step shaft, the inner ring of the conductive slip ring is fastened on the step shaft, and the polishing pad is SUBA 800.

(2) The ultraviolet light source is located right above the polishing disc. When the light source is turned on, the ultraviolet light can irradiate the surface of the wafer.

(3) The negative electrode of the external power supply is conducted to the counter electrode disc, and the positive electrode of the external power supply is conducted to the workpiece.

(4) The polishing solution spray head feeds the polishing solution into the contact area between the wafer and the polishing pad through the through holes. The supply flow of the polishing solution is 80 mL/min, the mass concentration of SiO₂ abrasive particle is 10 wt. %, and the particle size of SiO₂ abrasive particle is 25 nm. The composition of the polishing solution is shown in Table 1.

(5) The rotational speed of the GaN wafer is 250 rpm; the rotational speed of the polishing disc is 150 rpm; the polishing pressure is 6.5 psi; the intensity of the ultraviolet light is 175 mW·cm⁻²; and the polishing time is 1 hour.

(6) The conductive adhesive is heated to melt and the wafer is removed. Acetone, alcohol, 2 wt. % hydrofluoric acid and deionized water are successively used to clean the wafer, and then nitrogen is used to dry the wafer. The mass of the wafer is weighed and the surface roughness after polishing is measured.

TABLE 1
Embodiment conditions and photoelectrochemical mechanical polishing effects

| | | | | UV | Photoelectrochemical: | |
|---|---|---|---|---|---|---|
| | Voltage | K₂SO₄ | pH | intensity | Mechanical polishing | Removal rate |
| | E/V | (mol) | (H₂SO₄) | mW · cm⁻² | (area ratio) | (nm/h) |
| Embodiment 1 | 2.5 | 0.1 | 2 | 175 | 1:1.1 | 1200 |
| Embodiment 2 | 2.5 | 0 | 1 | 175 | 1:1.1 | 1550 |
| Embodiment 3 | 1.8 | 0.1 | 2 | 175 | 1:1.1 | 1100 |
| Embodiment 4 | 1.8 | 0 | 1 | 175 | 1:1.1 | 1520 |
| Embodiment 5 | 1.8 | 0.1 | 2 | 175 | 1:4 | 319.5 |
| Embodiment 6 | 0 | 0.1 | 2 | 175 | 1:1.1 | 32 |
| Embodiment 7 | 0 | 0 | 1 | 175 | 1:1.1 | 44 |

In Table 1, different removal rates correspond to the photochemical mechanical polishing process of the wafers with different processing conditions. The processed wafers in Embodiment 1 and Embodiment 2 were taken to measure their surface quality, and the measurement results are shown in FIGS. 7 and 8 respectively. Compared with the initial morphology of the wafer in FIG. 6, it can be seen that the surface of the wafer is significantly improved. The surface roughness was reduced by 0.48 nm respectively. In FIG. 7, the surface of the wafer is relatively flat, and clear atomic-scale steps can be seen. In FIG. 8, the surface roughness value of Ra can reach 0.1 nm. The scratch damage caused by diamond grinding on the surface of the original wafer was removed by polishing.

At last, it should be stated that the above various embodiments are only used to illustrate the technical solutions of the present disclosure without limitation; and despite reference to the aforementioned embodiments to make a detailed description of the present invention, those of ordinary skilled in the art should understand: the described technical solutions in above various embodiments may be modified or the part of or all technical features may be equivalently substituted; while these modifications or substitutions do not make the essence of their corresponding technical solutions deviate from the scope of the technical solutions of the embodiments of the present disclosure.

1. A semiconductor wafer photoelectrochemical mechanical polishing processing device, comparing:
a polishing pad having through holes;
a polishing disc having through holes, driving the polishing pad to mechanically polish a surface of a wafer;
a polishing solution source supplying a polishing solution, the polishing solution dripping on the wafer surface through the through holes of the polishing disc and the polishing pad;
an ultraviolet light source supplying ultraviolet light, the ultraviolet light irradiating the wafer through the through holes of the polishing disc and the polishing pad; and
an external power supply;
wherein
the wafer is connected to a positive electrode of the external power supply, and the polishing disc is connected to a negative electrode of the external power supply; and the external power supply, the wafer and the polishing disc form a closed circuit.

2. A semiconductor wafer photoelectrochemical mechanical polishing processing device, comparing:
a polishing pad having through holes;
a polishing disc having through holes, driving the polishing pad to mechanically polish a surface of a wafer;
a counter electrode disc having through holes, arranged between the polishing disc and the polishing pad;
a polishing solution source supplying a polishing solution, the polishing solution dripping on the wafer surface through the through holes of the polishing disc and the polishing pad;
an ultraviolet light source supplying ultraviolet light, the ultraviolet light irradiating the wafer through the through holes of the polishing disc and the polishing pad; and
an external power supply;
wherein
the wafer is connected to a positive electrode of the external power supply, and the counter electrode disc is connected to a negative electrode of the external power supply; and the external power supply, the wafer and the counter electrode disc form a closed circuit.

3. The semiconductor wafer photoelectrochemical mechanical polishing processing device according to claim 1, wherein the polishing solution is a chemical polishing solution which comprises abrasive particles.

4. The semiconductor wafer photoelectrochemical mechanical polishing processing device according to claim 1, wherein the polishing disc and the polishing pad are located above the wafer, and the ultraviolet light source is located above the polishing disc and the polishing pad.

5. The semiconductor wafer photoelectrochemical mechanical polishing processing device according to claim 1, wherein the polishing solution source is a polishing solution spray head which is located above the polishing disc.

6. The semiconductor wafer photoelectrochemical mechanical polishing processing device according to claim 1, wherein the through holes of the polishing disc are arranged radially from a center of the polishing disc to periphery; preferably, the through holes are arranged periodically along the radial direction of the polishing disc; preferably, a center part of the polishing disc is not provided with through hole, and only a position where the peripheral part of the polishing disc contacts with the wafer is provided with the through holes.

7. The semiconductor wafer photoelectrochemical mechanical polishing processing device according to claim 1, wherein layouts of the through holes of the polishing disc, the counter electrode and the polishing pad are consistent.

8. The semiconductor wafer photoelectrochemical mechanical polishing processing device according to claim 1, wherein the power supply of the external electric field is at least one of a direct-current power supply, a potentiostat, an electrochemical workstation and a dry battery.

9. The semiconductor wafer photoelectrochemical mechanical polishing processing device according to claim 1, wherein an area of the polishing pad is greater than that of the wafer; a preferred radius of the polishing pad is greater than a diameter of the wafer; a preferred radius of the polishing disc is greater than a diameter of the wafer; and preferably, the through holes of the polishing pad are arranged at a portion in contact with the wafer.

10. The semiconductor wafer photoelectrochemical mechanical polishing processing device according to claim 1, wherein an area ratio of photoelectrochemical action and mechanical action of the device is 1:12 to1:1.

11. A semiconductor wafer photoelectrochemical mechanical polishing processing method, mechanically polishing a wafer; mechanically polishing a polishing piece having through holes;
during polishing, ultraviolet light irradiating the wafer through the through holes;
during polishing, the polishing solution dripping on the surface of the wafer through the through holes, and the polishing solution comprising abrasive particles; and
during polishing, the wafer being used as an anode and being modified by photoelectrochemical oxidation under an external electric field.

12. The semiconductor wafer photoelectrochemical mechanical polishing processing method according to claim 11, wherein the polishing piece comprises polishing disc and polishing pad, and the layout of the through holes of the polishing disc is consistent with that of the polishing pad; and the polishing disc is used as a cathode.

13. The semiconductor wafer photoelectrochemical mechanical polishing processing method according to claim 12, comprising the following steps:
S1. fixing the wafer to a polishing head by means of conductive adhesive, after driving, the wafer rotating axially with the polishing head, wherein the polishing head is an electric conductor; adhering the polishing pad to the polishing disc, after driving, the polishing pad contacting the wafer surface and producing a relative motion;
S2. applying a positive potential to the wafer and a negative potential to the polishing disc; and
S3. during polishing, ultraviolet light irradiating the wafer successively passing through the through holes of the polishing disc and the polishing pad; and the polishing solution impregnating a contact area between the wafer and the polishing pad by the through holes of the polishing disc and the polishing pad.

14. The method according to claim 11, wherein the polishing piece comprises the polishing disc and the polishing pad, the counter electrode disc having through holes is arranged between the polishing disc and the polishing pad as a cathode; and the layouts of the through holes of the polishing disc, the counter electrode and the polishing pad are consistent.

15. The method according to claim 14, comprising the following steps:
S1. fixing the wafer to the polishing head by means of conductive adhesive, after driving, the wafer rotating axially with the polishing head, wherein the polishing head is an electric conductor; adhering the polishing pad to the counter electrode disc, and fixing the counter electrode disc to the polishing disc, after driving, the polishing pad contacting the wafer surface and producing a relative motion, wherein the counter electrode disc has through holes;
S2. applying a positive potential to the wafer and a negative potential to the disc-shaped counter electrode disc; and
S3. during polishing, ultraviolet light irradiating the wafer successively passing through the through holes of the polishing disc, the counter electrode disc and the polishing pad; and the polishing solution impregnating a contact area between the wafer and the polishing pad by the through holes of the polishing disc, the counter electrode disc and the polishing pad successively.

16. The method according to claim 12, wherein the wafer is connected to the positive electrode of the external power supply and the cathode to the negative electrode of the external power supply; and the external power supply, the wafer and the cathode form a closed circuit.

17. The method according to claim 11, wherein an area ratio of photoelectrochemical action and mechanical action is 1:12 to1:1.

18. The method according to claim 11, wherein the polishing disc and the polishing pad are located above the semiconductor wafer, and the ultraviolet light source is located above polishing disc.

19. The method according to claim 11, wherein the abrasive particle is cerium oxide or silicon oxide; a preferred particle size of the abrasive particle is 6 nm to 100 nm; a preferred concentration of the abrasive particle is 0.05-10 wt %; a supply flow of the polishing solution is 50 mL/min to 100 mL/min; and a rotational speed of the wafer is 100 rpm to 250 rpm, a rotational speed of the polishing disc is 60 to 150 rpm, a polishing pressure is 4 to 6.5 psi, and an intensity of the ultraviolet light is 50 to 175 mW·cm⁻².

20. The method according to claim 11, wherein the semiconductor wafer is a gallium nitride wafer.
